(19) United States
(12) Patent Application Publication
(10) Pub. No.: US 2026/0047372 A1
(43) Pub. Date: Feb. 12, 2026

(54) METHOD OF MANUFACTURING SEMICONDUCTOR DEVICE

(71) Applicant: Renesas Electronics Corporation, Tokyo (JP)

(72) Inventors: Yuya ABIKO, Tokyo (JP); Taiga TAKAHASHI, Tokyo (JP)

(21) Appl. No.: 19/230,293

(22) Filed: Jun. 6, 2025

(30) Foreign Application Priority Data
Aug. 9, 2024 (JP) 2024-133892

(51) Int. Cl. H01L 21/308; H01L 21/027; H01L 21/033; H10D 30/01; H10D 30/66; H10D 64/00; H10D 64/01; H10D 64/27

(52) U.S. Cl. CPC H01L 21/3081; H01L 21/0271; H01L 21/033; H10D 30/0295; H10D 30/0297; H10D 64/025; H10D 30/665; H10D 30/668; H10D 64/112; H10D 64/117; H10D 64/514; H10D 64/518

(57) ABSTRACT

A manufacturing method of a semiconductor device includes preparing a semiconductor substrate having an upper surface and a lower surface, forming a first mask having a plurality of openings on the upper surface divided into a first region and a second region, forming a second mask that exposes a portion of the first mask arranged in the first region and covers a portion arranged in the second region, etching the semiconductor substrate in the first region using the first mask and the second mask as a mask, removing the second mask, and etching the semiconductor substrate in the first region and the second region using the first mask as a mask.

### CROSS-REFERENCE TO RELATED APPLICATIONS

The disclosure of Japanese Patent Application No. 2024-133892 filed on Aug. 9, 2024, including the specification, drawings and abstract is incorporated herein by reference in its entirety.

### BACKGROUND

This disclosure relates to a method for manufacturing a semiconductor device.

There is a disclosed technique listed below.

### [Patent Document 1] Japanese Unexamined Patent Application Publication No. 2024-001723

Patent Document 1 discloses a semiconductor device with a trench formed therein.

### SUMMARY

There is a desire to improve the reliability of semiconductor devices.

Other challenges and novel features will become apparent from the description of this specification and the accompanying drawings.

According to one embodiment, the method for manufacturing a semiconductor device includes preparing a semiconductor substrate having an upper surface and a lower surface, forming a first mask having a plurality of openings on the upper surface divided into a first region and a second region, forming a second mask that exposes the portion of the first mask arranged in the first region and covers the portion arranged in the second region, etching the semiconductor substrate in the first region using the first and second masks as a mask, removing the second mask, and etching the semiconductor substrate in the first and second regions using the first mask as a mask.

According to one embodiment, the method for manufacturing a semiconductor device includes: (a) preparing a semiconductor substrate of a first conductivity type having an upper surface and a lower surface; (b) after step (a), forming a trench in the semiconductor substrate to reach a predetermined depth from the upper surface of the semiconductor substrate and to extend in a first direction in plan view; (c) after step (b), forming a first insulating film inside the trench; (d) after step (c), forming a field plate electrode to embed an inside of the trench via the first insulating film; (e) after step (d), selectively recessing other parts of the field plate electrode so that a part of the field plate electrode remains as a contact portion; (f) after step (e), recessing the first insulating film inside the trench so that a position of its upper surface becomes lower than a position of an upper surface of the field plate electrode; (g) after step (f), forming a gate insulating film on the semiconductor substrate inside the trench and forming a second insulating film on an upper surface and a side surface of the field plate electrode exposed from the first insulating film; (h) after step (g), forming a gate electrode to embed an inside of the trench on the field plate electrode recessed in step (e); (i) after step (h), forming an interlayer insulating film on an upper surface of the semiconductor substrate to cover the trench; (j) after step (i), forming a first hole, a second hole, and a third hole in the interlayer insulating film; and (k) after step (j), forming a source electrode and a gate wiring surrounding the source electrode in plan view on the interlayer insulating film. The gate electrode includes a first end in a first direction and a second end located opposite the first end in the first direction. The contact portion is formed inside the trench positioned between the gate electrode on the first end side and the gate electrode on the second end side. The first hole is formed to overlap the first end in plan view. The second hole is formed to overlap the second end in plan view. The third hole is formed to overlap the contact portion in plan view. The gate wiring is embedded in the first and second holes and is electrically connected to the gate electrode. The source electrode is embedded in the third hole and is electrically connected to the field plate electrode. In step (h), a connecting portion that connects the gate electrode on the first end side and the gate electrode on the second end side is formed inside the trench where the contact portion is formed, as a part of the gate electrode. Step (b) includes: forming a first mask having a plurality of openings on the upper surface of the semiconductor substrate divided into a first region and a second region; forming a second mask that exposes a portion of the first mask arranged in the first region and covers a portion of the first mask arranged in the second region; etching the semiconductor substrate in the first region using the first and second masks as a mask; removing the second mask; etching the semiconductor substrate in the first and second regions using the first mask as a mask; and removing the first mask.

According to the embodiment, it is possible to provide a method for manufacturing a semiconductor device that can improve reliability.

### BRIEF DESCRIPTION OF THE DRAWINGS

FIG. 1 is a plan view illustrating a semiconductor substrate in the method for manufacturing a semiconductor device according to a comparative example and embodiment 1.

FIG. 2 is a cross-sectional view illustrating a semiconductor substrate in the method for manufacturing a semiconductor device according to a comparative example and embodiment 1.

FIG. 3 is a cross-sectional view illustrating a semiconductor substrate in the method for manufacturing a semiconductor device according to a comparative example and embodiment 1.

FIG. 4 is a cross-sectional view illustrating a semiconductor substrate in the method for manufacturing a semiconductor device according to a comparative example and embodiment 1.

### FIG. 5 is a cross-sectional view illustrating a semiconductor substrate in the method for manufacturing a semiconductor device according to a comparative example and embodiment 1.

FIG. 6 is a cross-sectional view illustrating a semiconductor substrate in the method for manufacturing a semiconductor device according to embodiment 1.

FIG. 7 is a cross-sectional view illustrating a semiconductor substrate in the method for manufacturing a semiconductor device according to embodiment 1.

FIG. 8 is a cross-sectional view illustrating a semiconductor substrate in the method for manufacturing a semiconductor device according to embodiment 1.

FIG. 9 is a plan view illustrating a semiconductor device according to embodiment 2.

FIG. 10 is a plan view illustrating a semiconductor device according to embodiment 2.

FIG. 11 is a cross-sectional view illustrating a semiconductor device according to embodiment 2, showing the A-A and B-B sections of FIG. 10.

FIG. 12 is a cross-sectional view illustrating a method for manufacturing a semiconductor device according to embodiment 2, showing the A-A and B-B sections of FIG. 10.

FIG. 13 is a cross-sectional view illustrating a method for manufacturing a semiconductor device according to embodiment 2, showing the A-A and B-B sections of FIG. 10.

FIG. 14 is a cross-sectional view illustrating a method for manufacturing a semiconductor device according to embodiment 2, showing the A-A and B-B sections of FIG. 10.

FIG. 15 is a cross-sectional view illustrating a method for manufacturing a semiconductor device according to embodiment 2, showing the A-A and B-B sections of FIG. 10.

FIG. 16 is a cross-sectional view illustrating a method for manufacturing a semiconductor device according to embodiment 2, showing the A-A and B-B sections of FIG. 10.

FIG. 17 is a cross-sectional view illustrating a method for manufacturing a semiconductor device according to embodiment 2, showing the A-A and B-B sections of FIG. 10.

FIG. 18 is a cross-sectional view illustrating a method for manufacturing a semiconductor device according to embodiment 2, showing the A-A and B-B sections of FIG. 10.

FIG. 19 is a cross-sectional view illustrating a method for manufacturing a semiconductor device according to embodiment 2, showing the A-A and B-B sections of FIG. 10.

FIG. 20 is a cross-sectional view illustrating a method for manufacturing a semiconductor device according to embodiment 2, showing the A-A and B-B sections of FIG. 10.

FIG. 21 is a cross-sectional view illustrating a method for manufacturing a semiconductor device according to embodiment 2, showing the A-A and B-B sections of FIG. 10.

FIG. 22 is a cross-sectional view illustrating a method for manufacturing a semiconductor device according to embodiment 2, showing the A-A and B-B sections of FIG. 10.

FIG. 23 is a cross-sectional view illustrating a method for manufacturing a semiconductor device according to embodiment 2, showing the A-A and B-B sections of FIG. 10.

FIG. 24 is a cross-sectional view illustrating a method for manufacturing a semiconductor device according to embodiment 2, showing the A-A and B-B sections of FIG. 10.

FIG. 25 is a cross-sectional view illustrating a method for manufacturing a semiconductor device according to embodiment 2, showing the A-A and B-B sections of FIG. 10.

FIG. 26 is a cross-sectional view illustrating a method for manufacturing a semiconductor device according to embodiment 2, showing the A-A and B-B sections of FIG. 10.

### DETAILED DESCRIPTION

For clarity of explanation, the following description and drawings are appropriately omitted and simplified. In the drawings, the same elements are denoted by the same reference numerals, and a repetitive description thereof is omitted as necessary. Also, to avoid complexity in the figures, reference numerals are omitted as appropriate.

First, in the <Comparative Example>, the method for manufacturing a semiconductor device according to the comparative example will be explained. Then, in <Challenges Newly Found by the Inventor>, the challenges newly found by the inventor regarding the comparative example will be explained. Subsequently, in <Embodiment 1> and <Embodiment 2>, the methods for manufacturing semiconductor devices according to embodiments 1 and 2 will be explained. This will clarify the semiconductor devices and their manufacturing methods according to embodiments 1 and 2. Note that the method for manufacturing a semiconductor device according to the comparative example and the challenges newly found by the inventor are also within the scope of the technical concept of the embodiments.

### Comparative Example

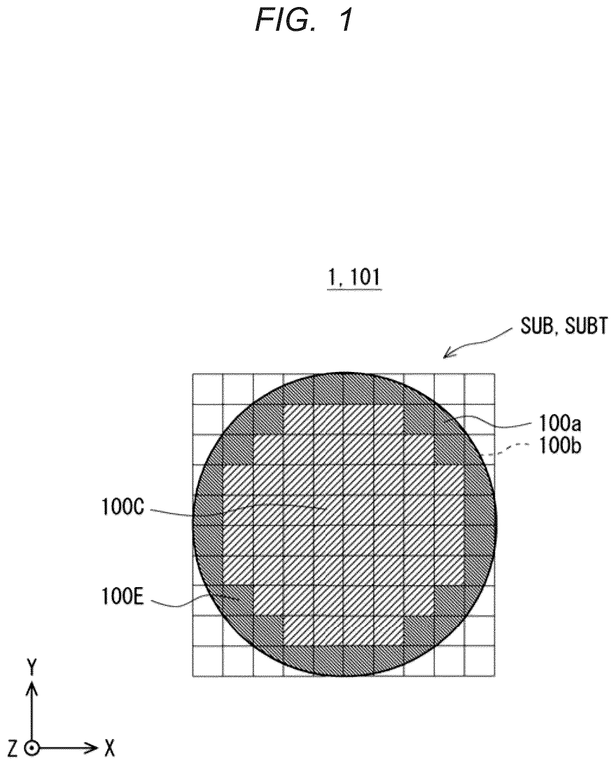

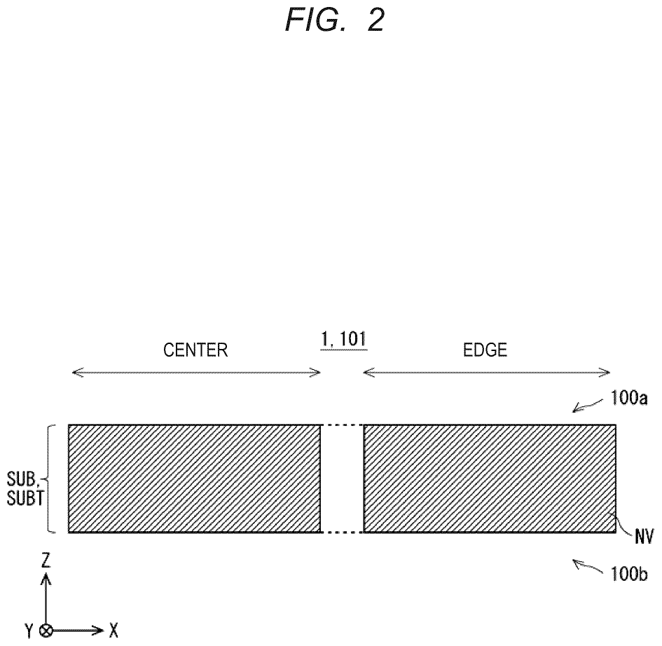

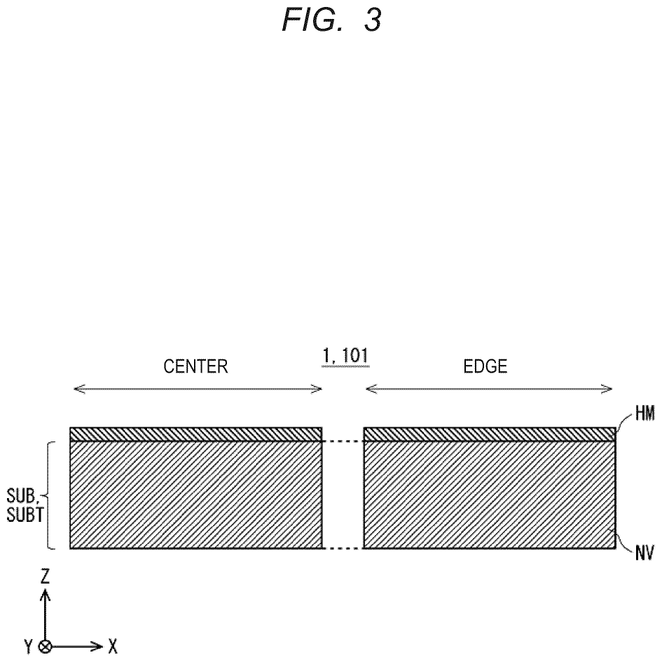

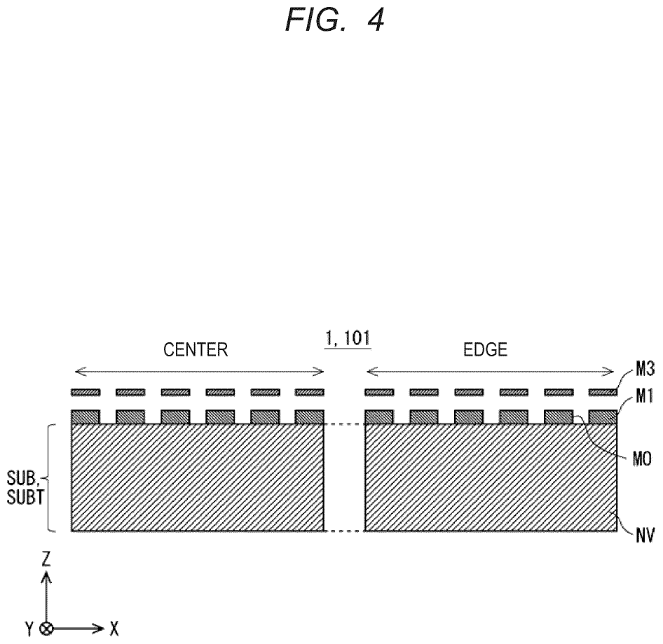

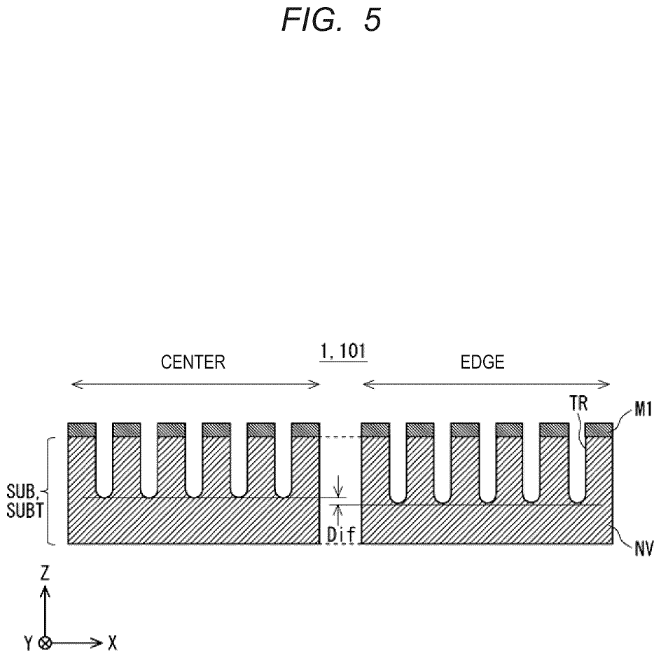

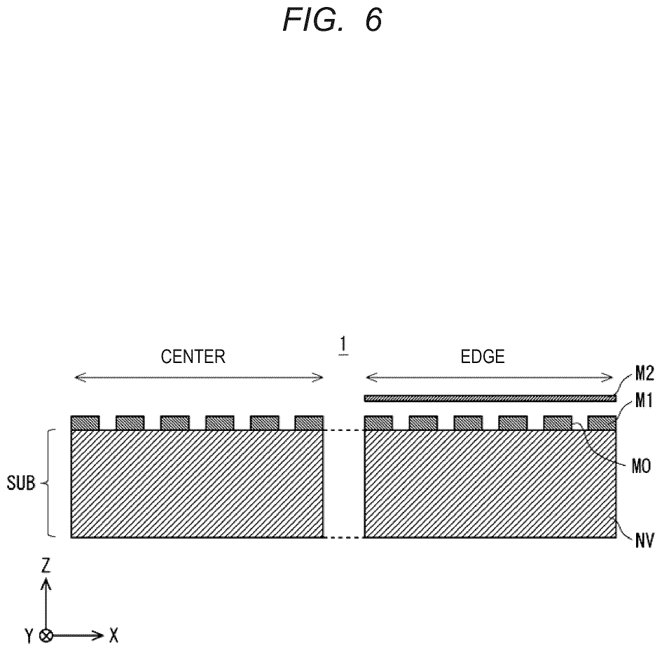

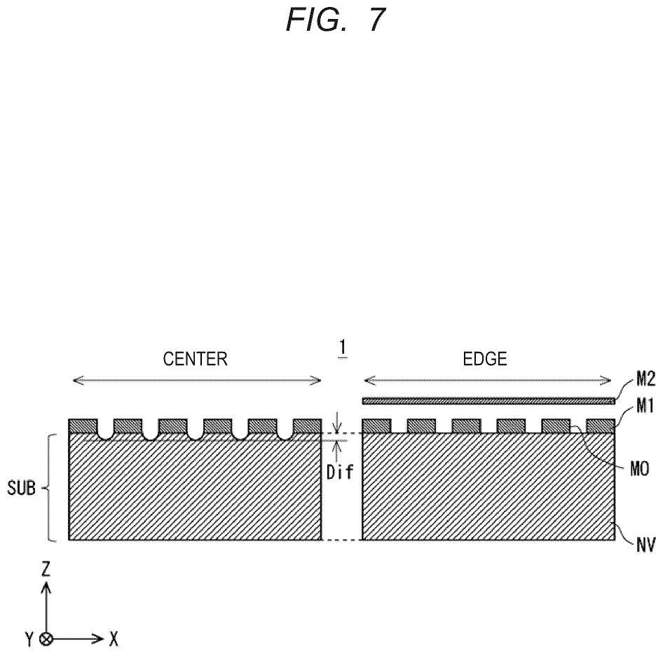

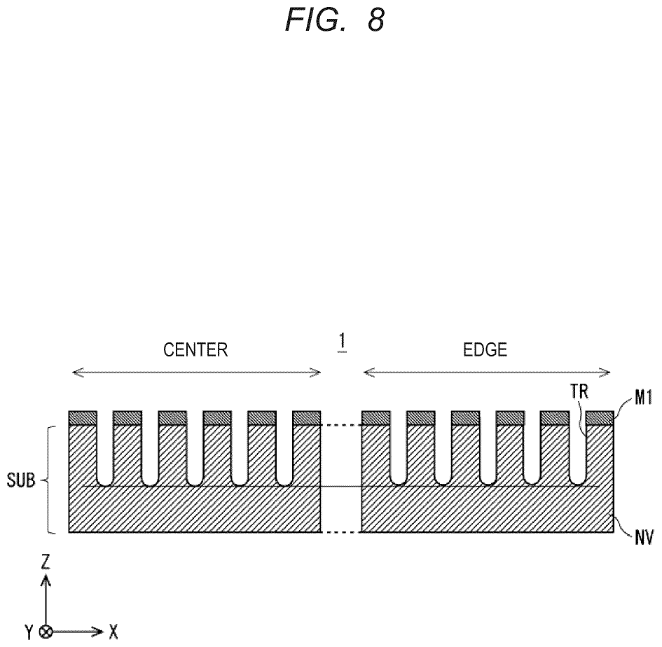

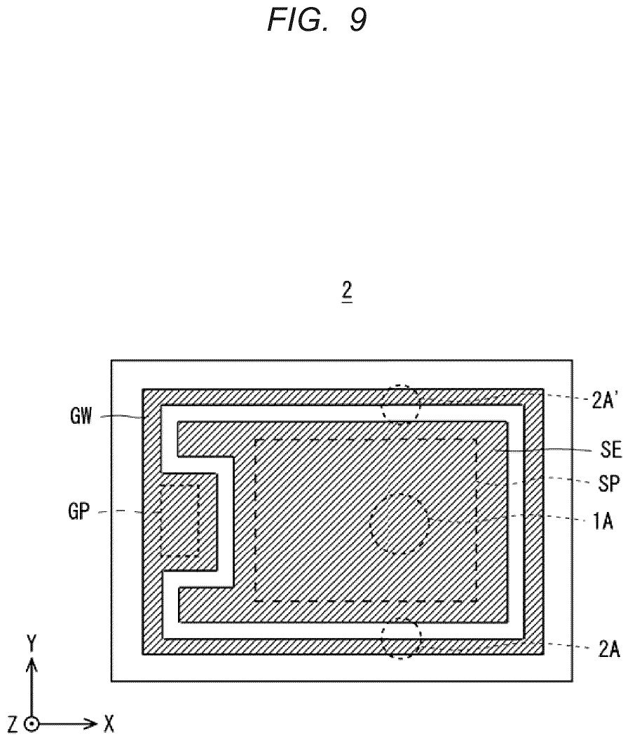

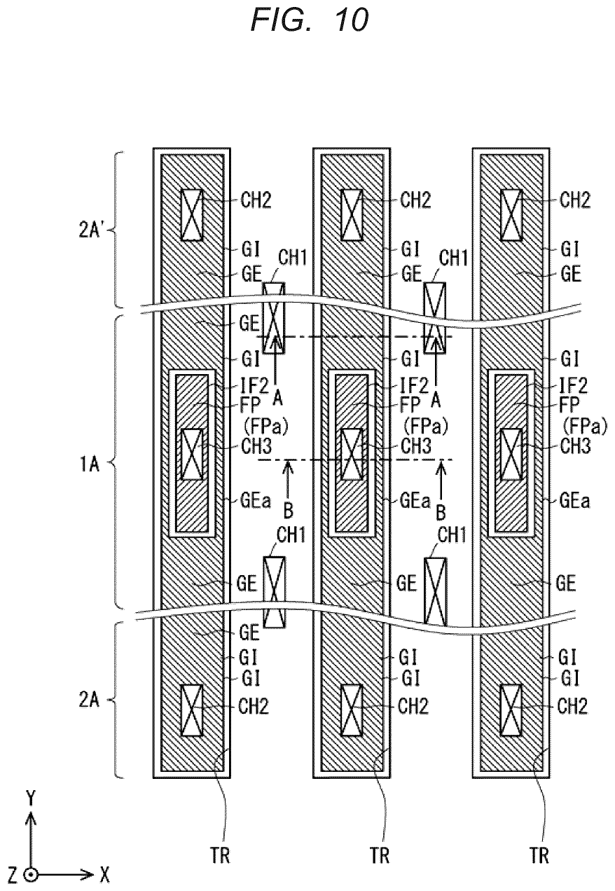

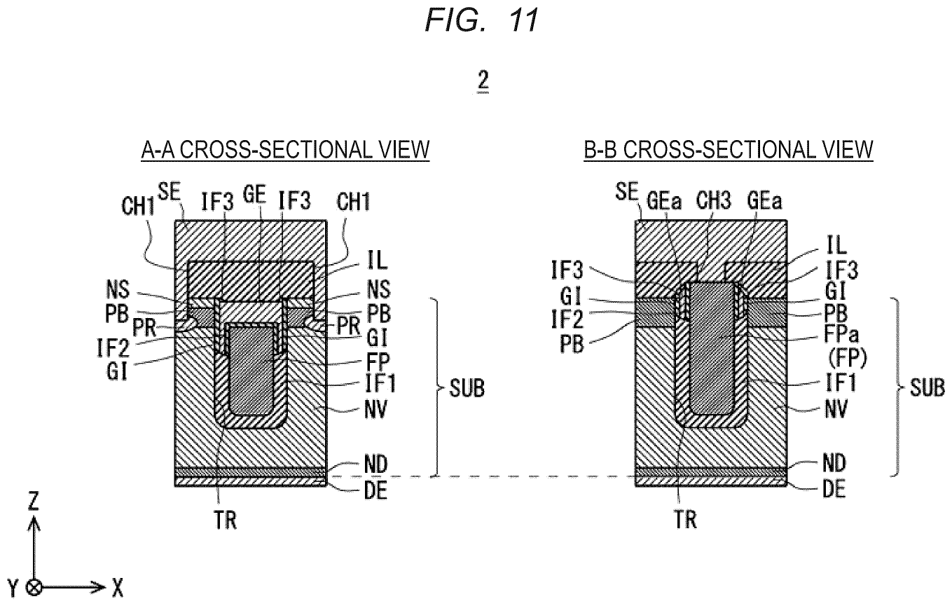

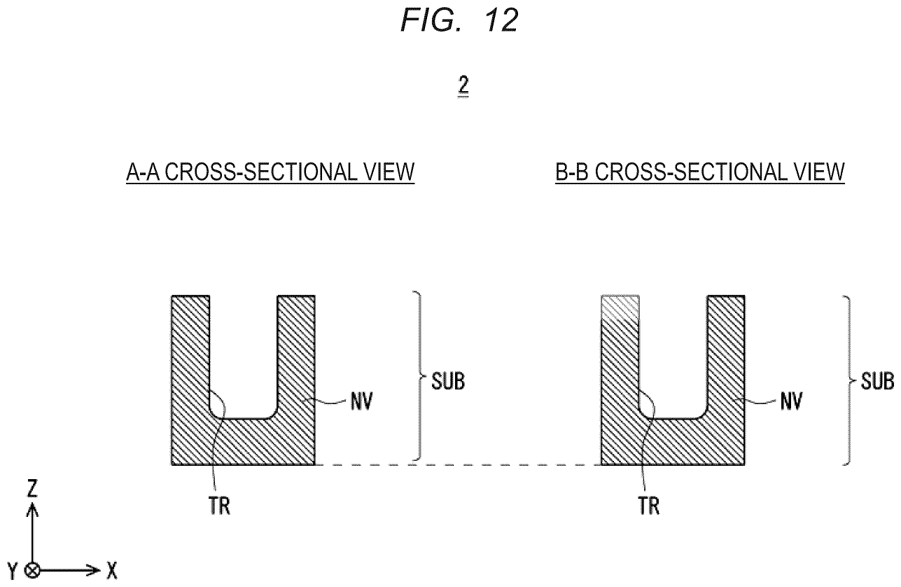

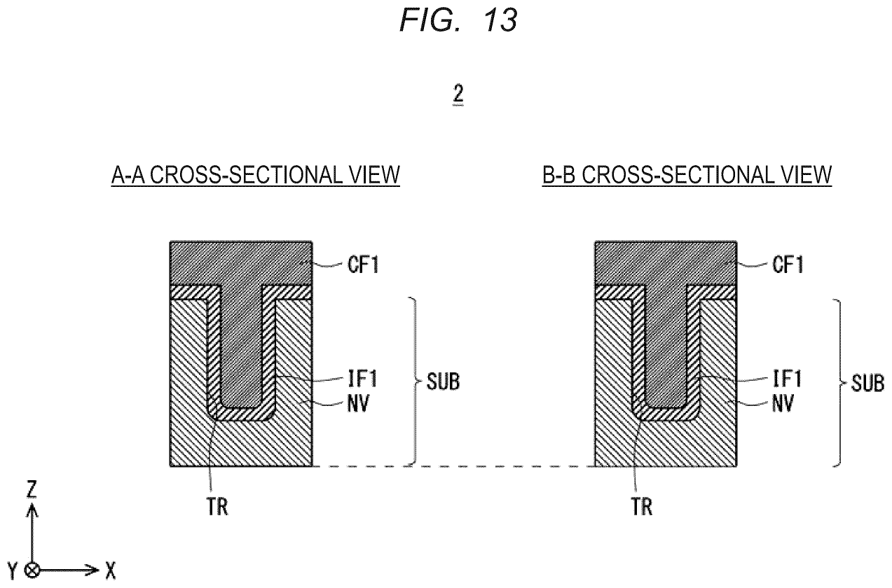

FIG. 1 is a plan view illustrating a semiconductor substrate SUB in the method for manufacturing a semiconductor device according to a comparative example and embodiment 1. FIGS. 2 to 5 are cross-sectional views illustrating a semiconductor substrate SUB in the method for manufacturing a semiconductor device according to a comparative example and embodiment 1. Note that FIGS. 1 to 5 are also used for the method of dividing the first region 100C and the second region 100E in embodiment 1. As shown in FIGS. 1 and 2, in the method for manufacturing the semiconductor device 101 according to the comparative example, first, a semiconductor substrate SUB having a first surface 100a and a second surface 100b is prepared. In FIG. 1, division lines for dividing the semiconductor substrate SUB into a plurality of regions to show the first surface 100a as a map are also shown.

Here, for the convenience of explaining the method for manufacturing the semiconductor device 101, an XYZ orthogonal coordinate system is introduced. For example, the direction perpendicular to the first surface 100a is defined as the Z-axis direction, and the plane parallel to the first surface 100a is defined as the XY plane. The +Z-axis direction is considered upward, and the −Z-axis direction is considered downward. The first surface 100a is referred to as the upper surface, and the second surface 100b is referred to as the lower surface. It should be noted that the terms upward and downward are used for convenience in explaining the manufacturing method of the semiconductor device 101 and do not indicate the actual orientation in which the semiconductor device 101 is placed.

The semiconductor substrate SUB includes, for example, an n-type drift region NV. Here, the semiconductor substrate SUB itself constitutes the n-type drift region NV, but the drift region NV may also be an n-type semiconductor layer grown on the n-type semiconductor substrate SUB by introducing phosphorus (P) through an epitaxial growth method.

The upper surface of the semiconductor substrate SUB is divided into a first region 100C and a second region 100E. The method of dividing the first region 100C and the second region 100E will be described later. Here, the first region 100C is described as including, for example, the central portion Center of the upper surface of the semiconductor substrate SUB when viewed from the Z-axis direction. Additionally, the second region 100E is described as including the outer peripheral portion Edge of the upper surface of the semiconductor substrate SUB when viewed from the Z-axis direction.

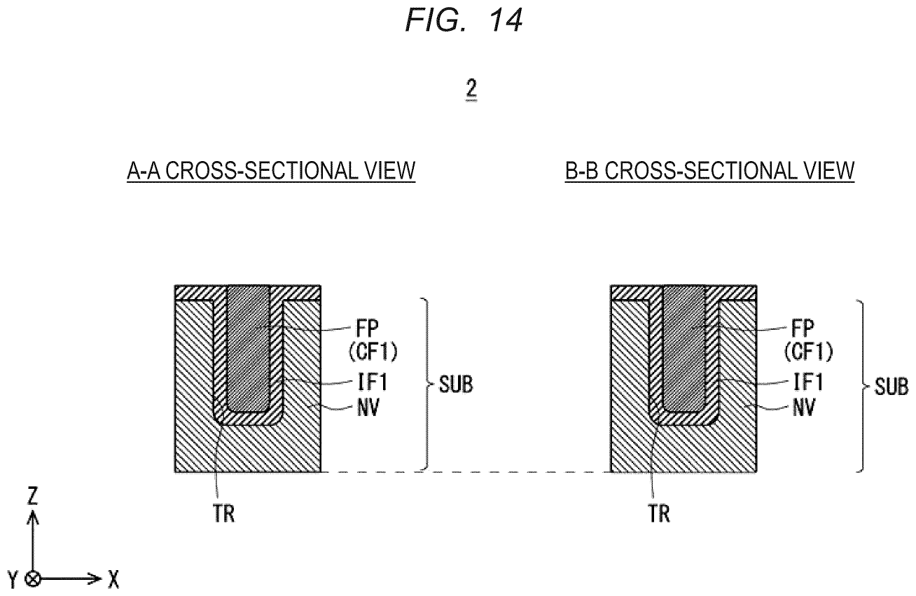

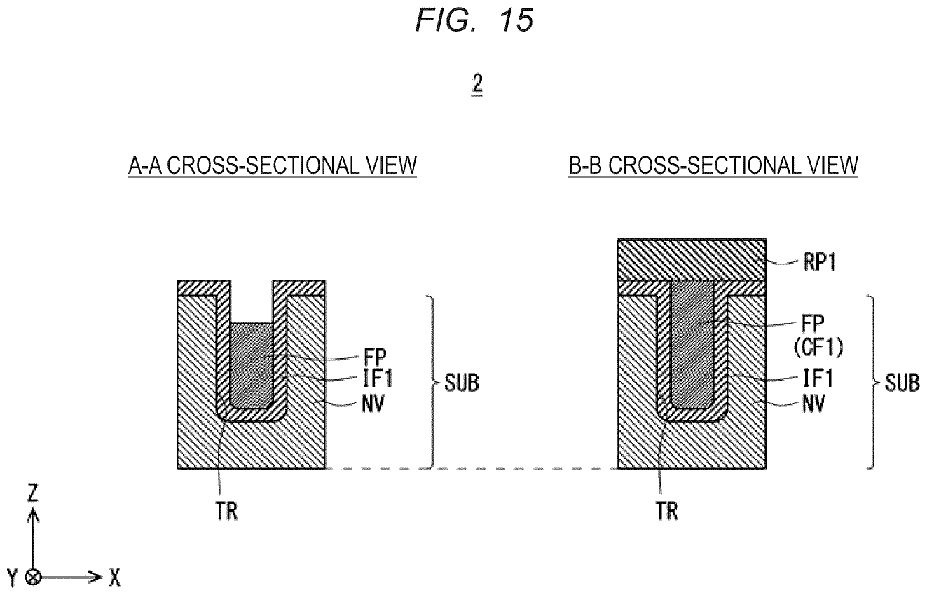

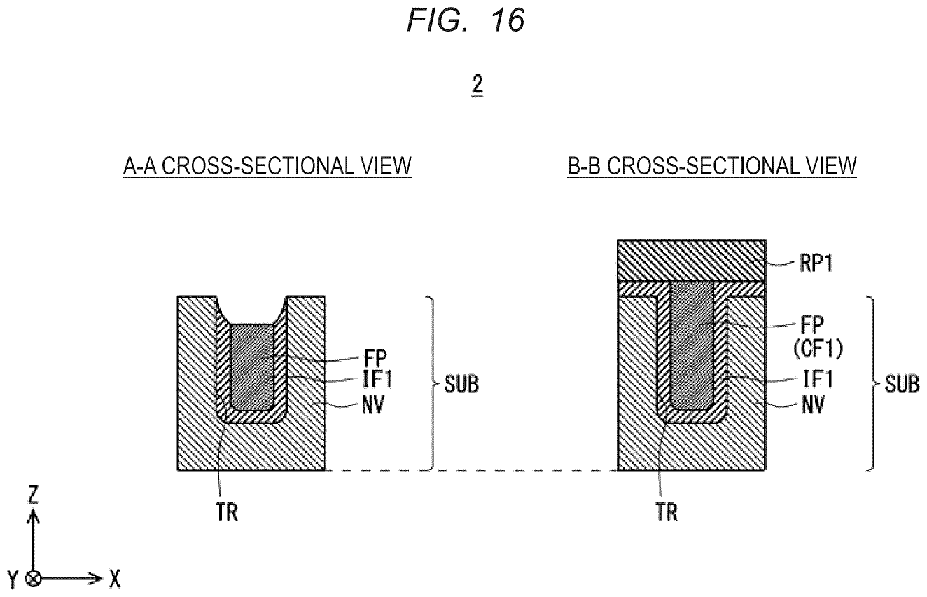

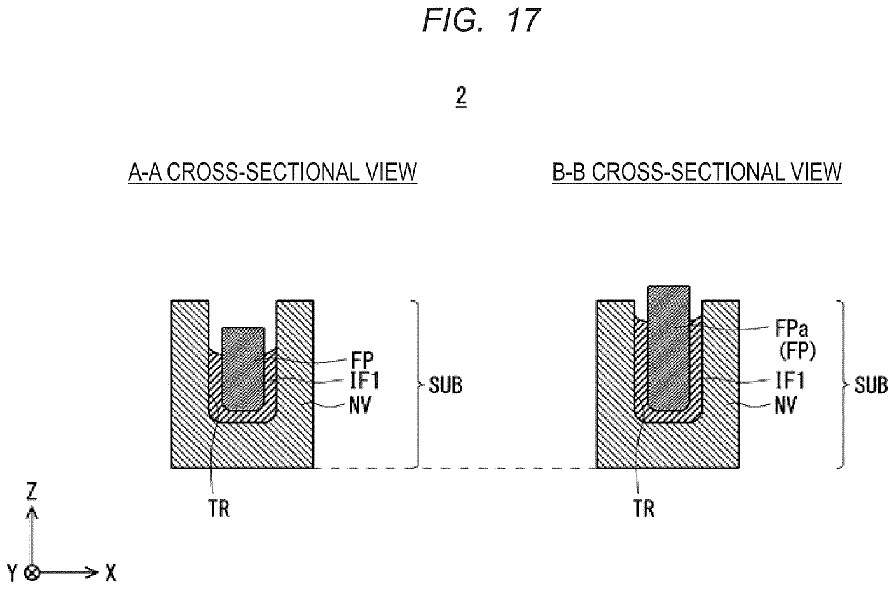

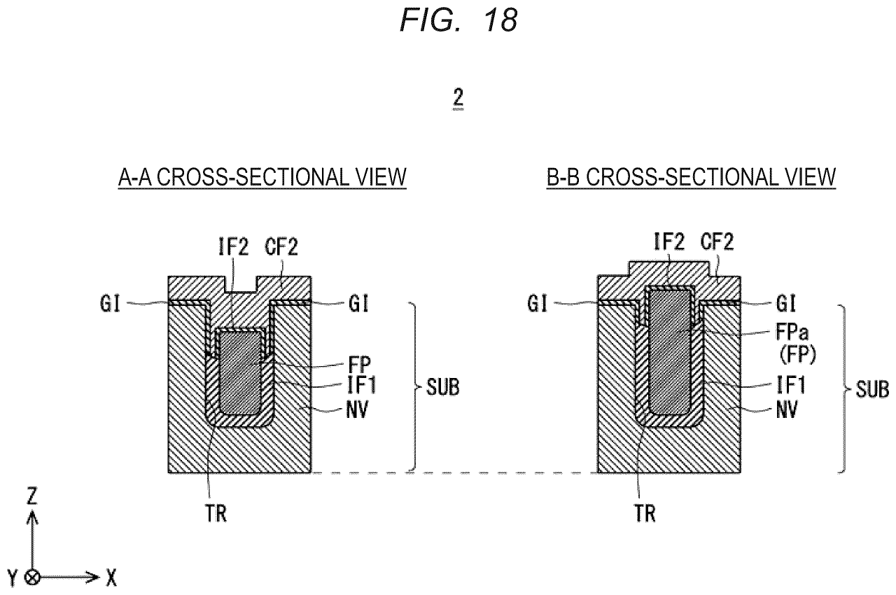

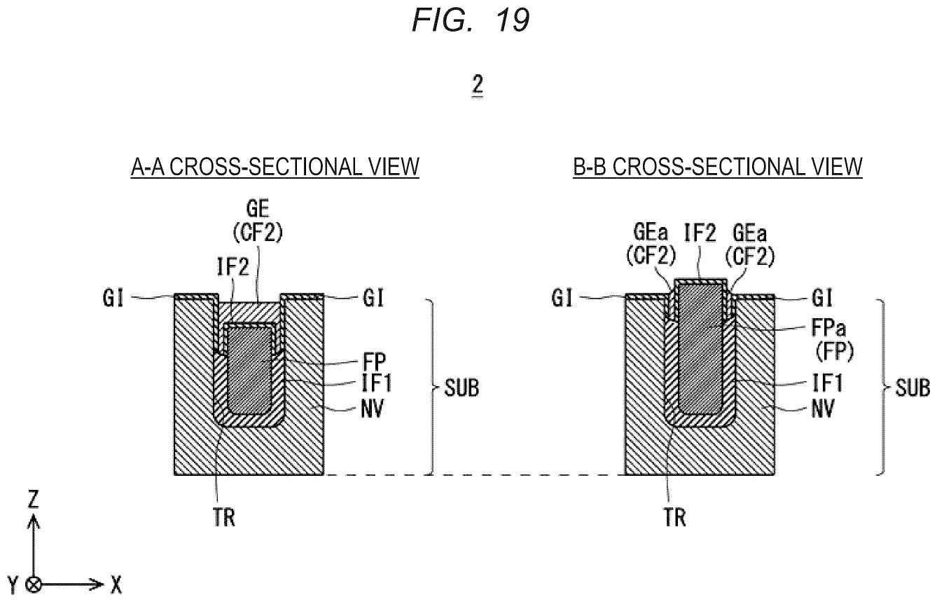

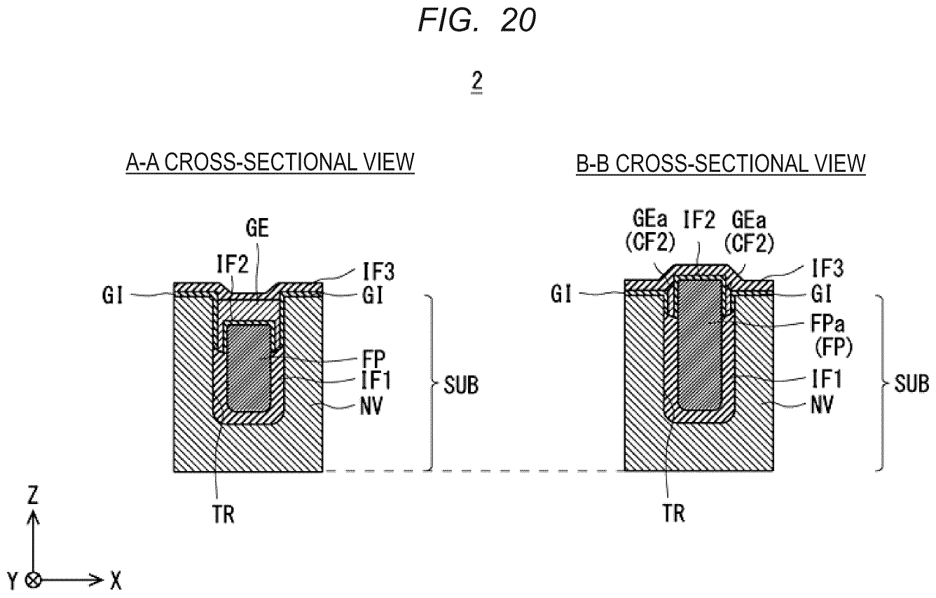

Next, as shown in FIG. 3, the first mask material HM is formed on the upper surface of the semiconductor substrate SUB. The first mask material HM is used to form the first mask M1 on the upper surface of the semiconductor substrate SUB. The first mask material HM may include, for example, a hard mask. The hard mask may include a silicon oxide film as an example. For instance, a hard mask including a silicon oxide film is formed on the semiconductor substrate SUB by a CVD (Chemical Vapor Deposition) method.

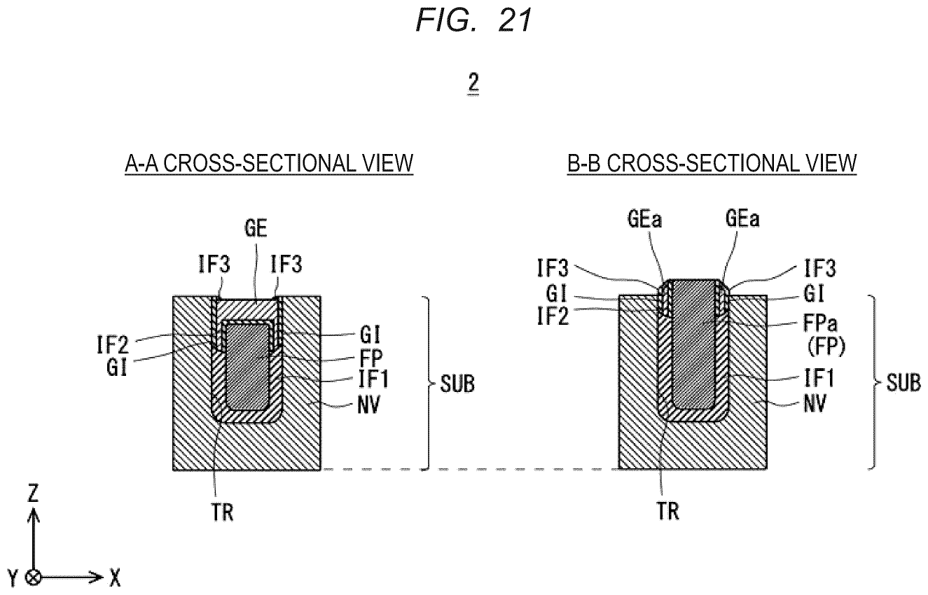

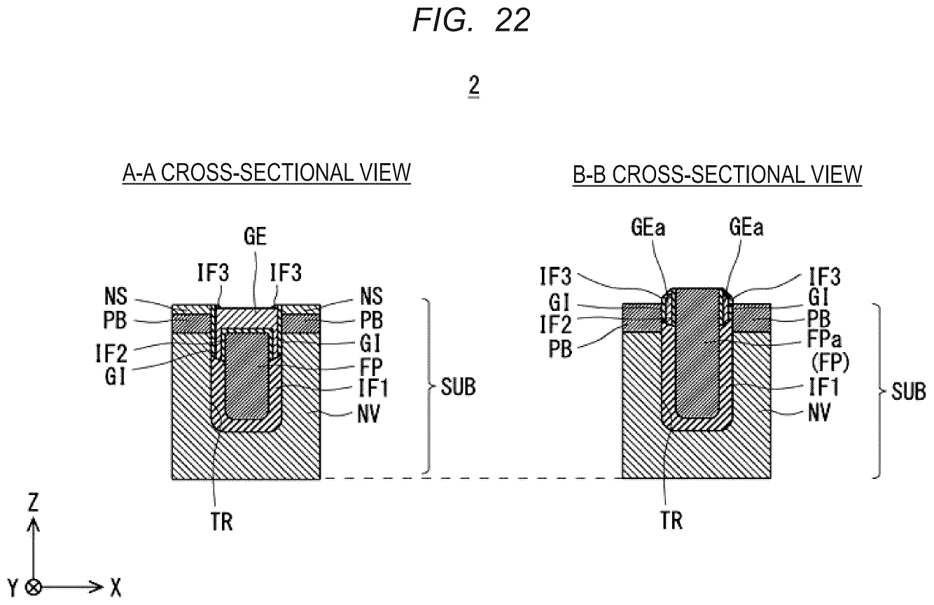

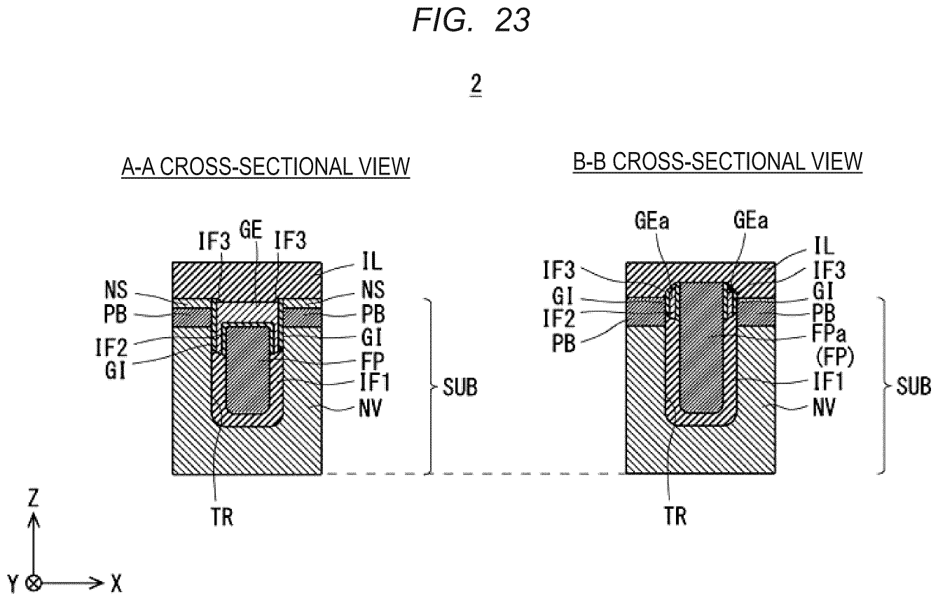

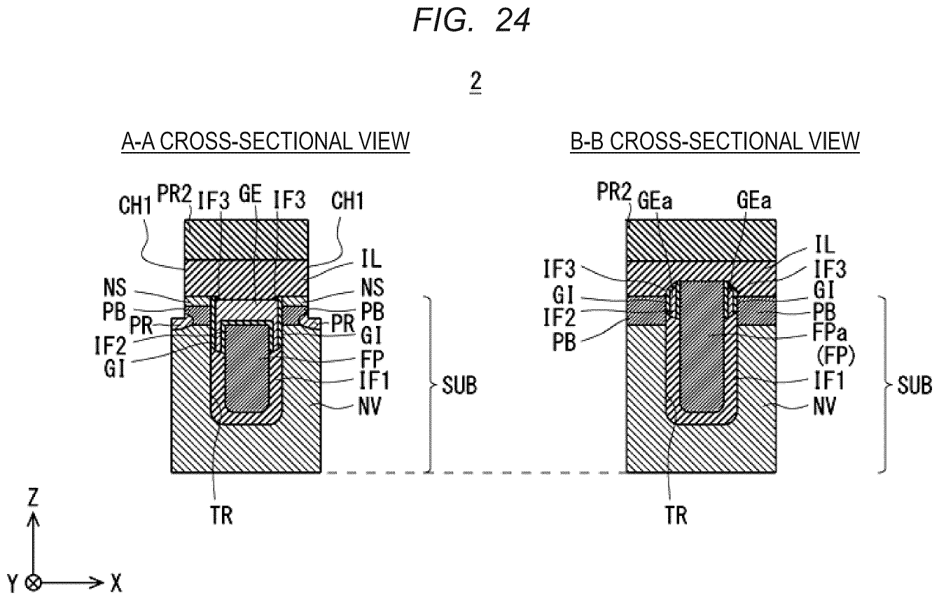

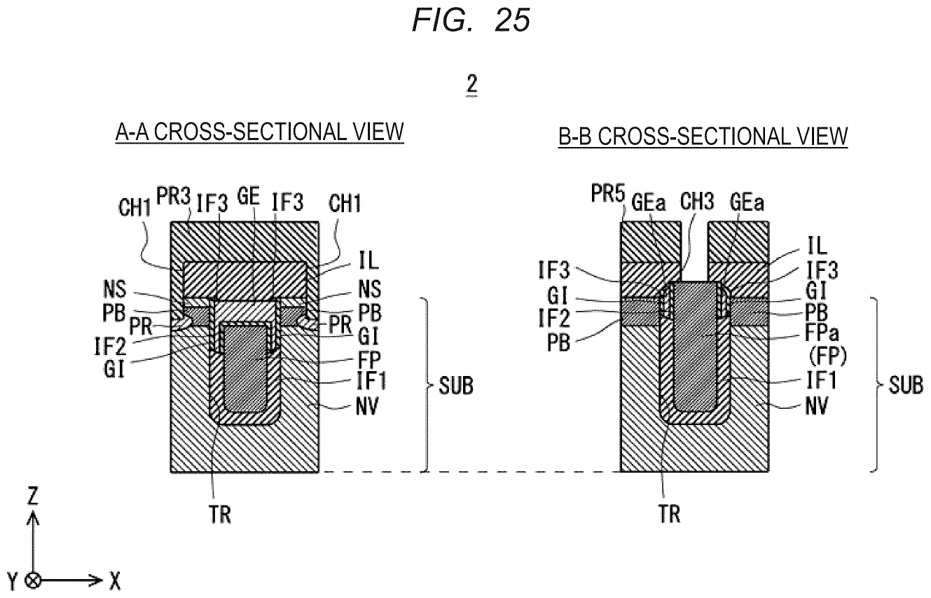

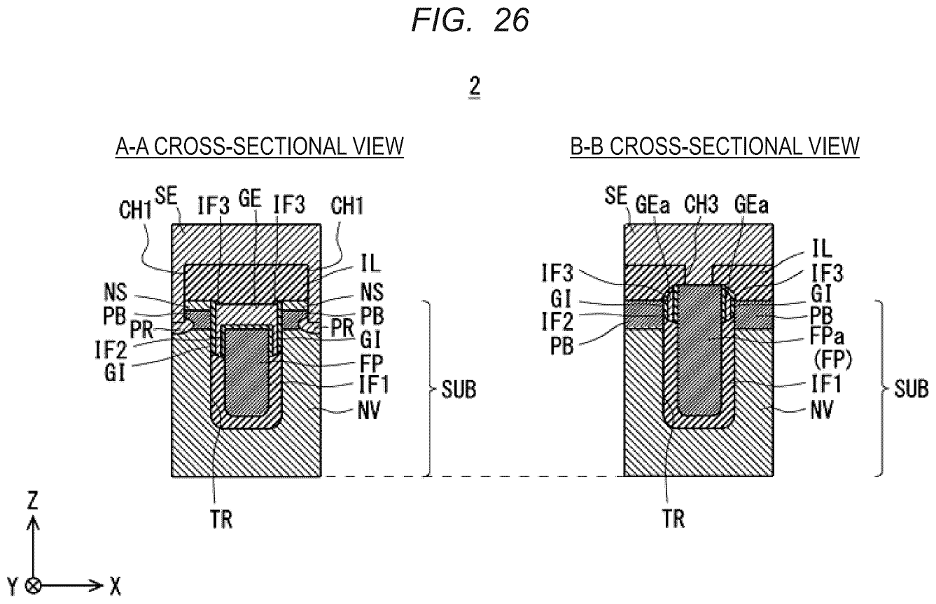

Next, as shown in FIG. 4, a first mask M1 having a plurality of openings MO is formed on the upper surface of the semiconductor substrate SUB, which is divided into the central portion Center and the outer peripheral portion Edge. The process of forming the first mask M1 includes, for example, the following steps.

First, as described above, the first mask material HM is formed on the upper surface of the semiconductor substrate SUB. Next, a third mask material is formed on the first mask material HM. The third mask material may include, for example, a photo resist. Then, the portion of the third mask material corresponding to the openings MO or the portion not corresponding to the openings MO is exposed. This allows, for example, the portion corresponding to the openings MO to be selectively removed by a developer solution or the like. Next, by removing the portion corresponding to the openings MO of the third mask material while leaving the portion not corresponding to the openings MO, the third mask M3 is formed. In this way, a third mask M3 having openings is formed using photolithography technology. The third mask M3 may include, for example, a resist pattern.

Next, the first mask material HM is etched using the third mask M3 as a mask to form the first mask M1. For example, by performing a dry etching process using the third mask M3, which includes a resist pattern, as a mask, a patterned first mask M1 is formed. In this way, in the process of forming the first mask M1, the openings MO for forming the trench TR in the semiconductor substrate SUB are patterned. The first mask M1 includes a hard mask.

Next, as shown in FIG. 5, the third mask M3 is removed. For example, the third mask M3, which includes a resist pattern, is removed by an ashing process. Then, a dry etching process is performed using the patterned first mask M1 as a mask. This forms the trench TR in the semiconductor substrate SUB. Subsequently, the first mask M1 may be removed by a wet etching process using a solution containing hydrofluoric acid or the like.

In the manufacturing method of the comparative example of the semiconductor device 101, it may be difficult to make the depth of the trench TR uniform within the plane of the upper surface of the semiconductor substrate SUB. For example, the depth of the trench TR in the outer peripheral portion Edge of the upper surface of the semiconductor substrate SUB may differ from the depth of the trench TR in the central portion Center. Specifically, depending on the conditions of the dry etching, the depth of the trench TR in the outer peripheral portion Edge may become deeper than the depth of the trench TR in the central portion Center.

For example, a difference Dif in etching depth may occur between the depth of the trench TR in the central portion Center and the depth of the trench TR in the outer peripheral portion Edge. This affects the operation of the semiconductor device 101 and reduces the yield of the semiconductor device 101, thereby decreasing the reliability of the semiconductor device 101.

### First Embodiment

Next, the manufacturing method of the semiconductor device according to the first embodiment will be described. First, the <Manufacturing Method of the Semiconductor Device> will be explained, followed by a description of <Application to Structures Other Than Trenches> and <Method of Dividing the First and Second Regions>.

### Manufacturing Method of the Semiconductor Device

The manufacturing method of the semiconductor device in this embodiment improves the uniformity of the depth of the trench TR in the central portion Center and the outer peripheral portion Edge on the upper surface of the semiconductor substrate SUB. Specifically, when forming the trench TR in the semiconductor substrate SUB, in this embodiment, selective etching by blank exposure is performed. Blank exposure is a process that leaves a mask including a photoresist only on the outer peripheral portion Edge, where the trench TR tends to become deeper. FIGS. 6 to 8 are cross-sectional views illustrating the semiconductor substrate SUB in the manufacturing method of the semiconductor device 1 according to the first embodiment.

The manufacturing method of the semiconductor device in this embodiment includes the same steps as the comparative example, as shown in FIGS. 2 to 4. This forms the first mask M1 having a plurality of openings MO on the upper surface of the semiconductor substrate SUB, which is divided into the central portion Center and the outer peripheral portion Edge. Then, the third mask M3 is removed by an ashing process.

Next, as shown in FIG. 6, a second mask M2 is formed to expose the portion placed in the central portion Center of the first mask M1 and cover the portion placed in the outer peripheral portion Edge of the first mask M1. The process of forming the second mask M2 includes, for example, the following steps.

First, a second mask material is formed on the first mask M1. The second mask material may include a photoresist. Next, the portion of the second mask material corresponding to the central portion Center or the portion corresponding to the outer peripheral portion Edge is exposed. This allows, for example, the portion corresponding to the central portion Center to be selectively removed by a developer solution or the like. Next, by removing the portion corresponding to the central portion Center of the second mask material while leaving the portion corresponding to the outer peripheral portion Edge, the second mask M2 is formed. In this way, the second mask M2 is formed using photolithography technology. The second mask M2 includes a photoresist. Therefore, the second mask M2 includes a resist pattern.

Next, as shown in FIG. 7, the semiconductor substrate SUB in the central portion Center is etched using the first mask M1 and the second mask M2 as masks. Specifically, in the central portion Center on the upper surface of the semiconductor substrate SUB, a dry etching process is performed using the first mask M1 having openings MO as a mask. When etching using the first mask M1 as a mask, the semiconductor substrate SUB may be etched using plasma. In this way, a part of the trench TR is formed in the semiconductor substrate SUB. As will be described later, it is preferable that the etching depth of a part of the trench TR is the difference Dif. On the other hand, in the outer peripheral portion Edge on the upper surface, the semiconductor substrate SUB is not etched because it is covered by the second mask M2.

Next, as shown in FIG. 8, the second mask M2 is removed. For example, the second mask M2, which includes a resist pattern, is removed by an ashing process. Then, the semiconductor substrate SUB in the central portion Center and the outer peripheral portion Edge is etched using the first mask M1 having opening MO as a mask. Specifically, for example, a dry etching process is performed to form the trench TR in the semiconductor substrate SUB. When forming the trench TR, the semiconductor substrate SUB may be etched using plasma. Subsequently, the first mask M1, which includes a silicon oxide film or the like, may be removed by a wet etching process using a solution containing hydrofluoric acid or the like.

In the manufacturing method of the semiconductor device 1 in the first embodiment, when forming the trench TR, first, the central portion Center is etched using the second mask M2 covering the peripheral portion Edge as a mask. This allows the trench TR in the central portion Center to be etched in advance by the depth of the aforementioned difference Dif. Then, the entire upper surface of the semiconductor substrate SUB, including the central portion Center and the outer peripheral portion Edge, is etched. This allows the depth of the trench TR to be made uniform within the plane of the upper surface of the semiconductor substrate SUB. Therefore, the yield of the semiconductor device 1 can be improved, and the reliability of the semiconductor device 1 can be enhanced.

### Application to Structures Other than Trenches

In the manufacturing method of the semiconductor device 1 in this embodiment, the etching of the semiconductor substrate SUB is not limited to etching for forming the trench TR. For example, it may be applied to etching for forming structures other than the trench TR, such as impurity regions of a super junction. In the following <Method of Dividing the First and Second Regions>, the etching depth is described as not limited to the depth of the trench TR. Therefore, the etching depth includes the depth of the trench TR but is not limited to the depth of the trench TR.

### Method for Dividing the First Region and the Second Region

Next, the method for dividing the first region 100C and the second region 100E will be described. In the aforementioned comparative example and the first embodiment, the first region 100C includes the central portion Center of the upper surface of the semiconductor substrate SUB, and the second region 100E includes the outer peripheral portion Edge of the upper surface of the semiconductor substrate SUB, but this is not limited to these. The first region 100C and the second region 100E may be divided by the following method. Therefore, depending on the conditions, the first region 100C may include portions other than the central portion Center of the upper surface of the semiconductor substrate SUB, and the second region 100E may include portions other than the outer peripheral portion Edge of the upper surface of the semiconductor substrate SUB.

The manufacturing method of the semiconductor device of this embodiment further includes a step of obtaining the in-plane distribution of the etching depth and a step of dividing the first region 100C and the second region 100E. The step of obtaining the in-plane distribution of the etching depth involves using the first mask M1 as a mask to obtain the in-plane distribution on the upper surface of a test semiconductor substrate SUBT, which includes the same material as the semiconductor substrate SUB, when etched. The step of dividing the first region 100C and the second region 100E is based on the obtained in-plane distribution.

The step of obtaining the in-plane distribution of the etching depth may include a step where the semiconductor substrate SUB in the comparative example is replaced with the test semiconductor substrate SUBT. Hereinafter, the semiconductor substrate SUB shown in FIGS. 2 to 5 will be described as being replaced with the test semiconductor substrate SUBT. First, as shown in FIG. 2, the test semiconductor substrate SUBT is prepared. The test semiconductor substrate SUBT includes the same material as the semiconductor substrate SUB.

Next, as shown in FIGS. 3 to 4, the first mask M1 is formed on the upper surface of the test semiconductor substrate SUBT. Then, as shown in FIG. 5, the test semiconductor substrate SUBT is etched using the first mask M1 as a mask. Next, the etching depth at a plurality of positions on the upper surface of the etched test semiconductor substrate SUBT is obtained. For example, the etching depth at a plurality of positions may be obtained by OCD (Optical Critical Dimension) measurement.

When dividing the first region 100C and the second region 100E, for example, a threshold for the etching depth may be set. Portions with an etching depth shallower than the threshold may be classified as the first region 100C, and portions with an etching depth equal to or greater than the threshold may be classified as the second region 100E.

Furthermore, as shown in FIG. 5, the process may further include obtaining the difference Dif between the etching depth of the divided first region 100C (e.g., central portion Center) and the etching depth of the divided second region 100E (e.g., outer peripheral portion Edge). The difference Dif may be the difference between the average value of the first region 100C and the average value of the second region 100E, or other indicators such as the difference between the central value of the first region 100C and the central value of the second region 100E may be used. As shown in FIG. 7, in the step of etching the semiconductor substrate SUB in the first region 100C, the semiconductor substrate SUB may be etched based on the obtained difference Dif.

In this way, by obtaining the in-plane distribution of the etching depth in advance using a test semiconductor substrate SUBT that includes the same material as the semiconductor substrate SUB, the division of the first region 100C and the second region 100E can be optimized. Therefore, the etching depth of the first region is 100C and the second region 100E can be made uniform. This can improve the yield of the semiconductor device 1 and enhance the reliability of the semiconductor device 1.

Moreover, since the difference Dif between the etching depth of the first region 100C and the etching depth of the second region 100E can be obtained in advance, the extra etching depth performed on the first region 100C can be optimized.

### Second Embodiment

Next, the semiconductor device of the second embodiment will be described. First, the <Structure of the Semiconductor Device> will be explained, followed by the <Manufacturing Method of the Semiconductor Device>.

### Structure of the Semiconductor Device

FIGS. 9 and 10 are plan views illustrating the semiconductor device 2 according to the second embodiment. FIG. 11 is a cross-sectional view illustrating the semiconductor device 2 according to the second embodiment, showing the A-A and B-B cross-sections of FIG. 10. As shown in FIGS. 9 and 10, semiconductor device 2 of this embodiment includes a MOSFET with a trench gate structure as a semiconductor element. The semiconductor device 2 particularly has a split gate structure with a gate electrode GE and a field plate electrode FP. The semiconductor device 2 in the first region 100C (e.g., central portion Center) and the second region 100E (e.g., outer peripheral portion Edge) of the semiconductor substrate SUB has a similar configuration. Therefore, the figures shown from FIG. 9 onwards illustrate either the semiconductor device 2 in the first region 100C (e.g., central portion Center) or the second region 100E (e.g., outer peripheral portion Edge).

FIG. 9 mainly shows the wiring pattern formed above the semiconductor substrate SUB. FIG. 10 shows the structure below the wiring pattern shown in FIG. 9. Specifically, FIG. 10 shows the structure of the trench gate formed in the semiconductor substrate SUB.

As shown in FIG. 9, the majority of the upper part of the semiconductor device 2 is covered by a source electrode (fixed potential supply wiring) SE. The gate wiring GW is provided along the outer periphery of the semiconductor device 2, surrounding the source electrode SE in plain view. Although not shown here, the source electrode SE and the gate wiring GW are covered with a protective film such as a polyimide film. An opening is provided in part of the protective film, and the source electrode SE and the gate wiring GW exposed at the opening become the source pad SP and the gate pad GP. By connecting external connection members such as wire bonding or clips (copper plates) to the source pad SP and the gate pad GP, the semiconductor device 2 is electrically connected to other semiconductor chips or wiring boards.

Additionally, the semiconductor device 2 includes region 1A and regions 2A and 2A′ that surround region 1A in plain view. Region 1A is a cell region where major semiconductor elements such as a plurality of MOSFETs are formed. Regions 2A and 2A′ are peripheral regions used for connecting the gate wiring GW to the gate electrode GE, etc. The structure of region 2A′ is a mirror image of the structure of region 2A on the drawing.

As shown in FIG. 10, a plurality of trenches TR extend in the Y-axis direction and are adjacent to each other in the X-axis direction. Inside the trench TR, a field plate (fixed potential electrode) electrode FP is formed at the bottom of the trench TR, and a gate electrode GE is formed at the top of the trench TR. Therefore, in the figure, the gate electrode GE is exposed. The field plate electrode FP and the gate electrode GE extend in the Y direction along the trench TR.

A part of the field plate electrode FP forms a contact portion FPa. The field plate electrode FP constituting the contact portion FPa is formed not only at the bottom of the trench TR but also at the top of the trench TR inside the trench TR of region 1A. Therefore, in the figure, the contact portion FPa is exposed.

The contact portion FPa divides the gate electrode GE into region 2A side and region 2A′ side. However, the gate electrode GE includes a connecting portion GEa. The connecting portion GEa connects the gate electrode GE on the region 2A side and the gate electrode GE on the region 2A′ side inside the trench TR where the contact portion FPa is formed. Additionally, the connecting portion GEa is formed on both side surfaces of the contact portion FPa via the insulating film IF2 in the X direction.

Below, the cross-sectional structure of the semiconductor device 2 will be described using FIG. 11. As shown in FIG. 11, the semiconductor device 2 includes a semiconductor substrate SUB having an upper surface and a lower surface. The semiconductor substrate SUB has a low-concentration n-type drift region NV. Hereinafter, a laminate consisting of an n-type silicon substrate and an n-type semiconductor layer will also be described as the semiconductor substrate SUB.

The semiconductor substrate SUB has a plurality of trenches TR formed to reach a predetermined depth from the upper surface of the semiconductor substrate SUB. Inside the trench TR, a field plate electrode FP is formed via an insulating film IF1 at the bottom of the trench TR. The position of the upper surface of the insulating film IF1 is lower than the position of the upper surface of the field plate electrode FP. An insulation film IF2 is formed on the upper and side surfaces of the field plate electrode FP exposed from the insulating film IF1. Additionally, a gate insulating film GI is formed on the semiconductor substrate SUB inside the trench TR.

Inside the trench TR, a gate electrode GE is formed at the top of the trench TR. The gate electrode GE is electrically insulated from the field plate electrode FP by the insulating film IF2 and electrically insulated from the semiconductor substrate SUB by the gate insulating film GI. Furthermore, the gate electrode GE is formed via the gate insulating film GI and the insulating film IF2 between the field plate electrode FP exposed from the insulating film IF1 and the semiconductor substrate SUB.

The upper surface of the gate electrode GE is slightly recessed compared to the upper surface of the semiconductor substrate SUB. On a portion of the upper surface of the gate electrode GE, an insulation film IF3 is formed so as to be in contact with the gate insulating film GI.

The gate electrode GE and the field plate electrode FP include, for example, a polycrystalline silicon film into which n-type impurities are introduced. The insulation films IF1, IF2, IF3, and the gate insulation film GI include, for example, a silicon oxide film. The thickness of the insulating film IF1 is greater than that of each of the insulating films IF2, IF3, and the gate insulating film GI.

On the upper surface side of the semiconductor substrate SUB, a p-type body region PB is formed to be shallower than the trench TR. In the body region PB, an n-type source region NS is formed. The source region NS has a higher impurity concentration than the drift region NV.

On the lower surface side of the semiconductor substrate SUB, an n-type drain region ND is formed. The drain region ND has a higher impurity concentration than the drift region NV. Below the lower surface of the semiconductor substrate SUB, a drain electrode DE is formed. The drain electrode DE includes, for example, a single-layer metal film such as an aluminum film, titanium film, nickel film, gold film, or silver film, or a laminated film formed by appropriately laminating these metal films.

On the upper surface of the semiconductor substrate SUB, an interlayer insulating film IL is formed to cover the trench TR. The interlayer insulating film IL may include, for example, a silicon oxide film. The interlayer insulating film IL may also be a laminated film of a thin silicon oxide film and a thick silicon oxide film containing phosphorus (PSG: Phospho Silicate Glass film).

In the interlayer insulating film IL, the source region NS, and the body region PB, a hole CH1 is formed. At the bottom of the hole CH1, a high concentration region PR is formed in the body region PB. The high concentration region PR has a higher impurity concentration than the body region PB.

On the interlayer insulating film IL, a source electrode SE is formed. The source electrode SE is embedded within the hole CH1. The source electrode SE is electrically connected to the source region NS, the body region PB, and the high concentration region PR. The source electrode SE supplies a source potential (fixed potential) to these regions.

As shown in FIG. 10, the gate electrode GE includes a first end on the region 2A side and a second end on region 2A′ side in the Y direction. In the interlayer insulating film IL, a hole CH2 is formed. The hole CH2 on the region 2A side is formed to overlap with the first end of the gate electrode GE in plain view. The hole CH2 on the region 2A′ side is formed to overlap with the second end of the gate electrode GE in plain view.

The first end of the gate electrode GE is the location where the hole CH2 of region 2A is provided, adjacent to the body region PB where the source region NS is not formed. Similarly, the second end of the gate electrode GE is the location where the hole CH2 of region 2A′ is provided, adjacent to the body region PB where the source region NS is not formed.

On the interlayer insulating film IL, a gate wiring GW is formed. The gate wiring GW is embedded within the hole CH2. The gate wiring GW is electrically connected to the gate electrode GE. The gate wiring GW supplies a gate potential to the gate electrode GE.

Returning to FIG. 11, a part of the field plate electrode FP forms the contact portion FPa. The contact portion FPa is formed inside the trench TR, located between the gate electrode GE on the region 2A side (first end side) and the gate electrode GE on the region 2A′ side (second end side), not only at the bottom of the trench TR but also at the top of the trench TR.

The position of the upper surface of the insulating film IF1 in contact with the field plate electrode FP, other than the contact portion FPa, is lower than the position of the upper surface of the insulating film IF1 in contact with the contact portion FPa. That is, the position of the upper surface of the insulating film IF1 in the A-A cross-section is located at a predetermined depth from the upper surface of the semiconductor substrate SUB. The position of the upper surface of the insulating film IF1 in the B-B cross-section is located at a predetermined depth from the upper surface of the semiconductor substrate SUB. Moreover, the position of the upper surface of the contact portion FPa is higher than the position of the upper surface of the semiconductor substrate SUB, located at a predetermined height from the upper surface of the semiconductor substrate SUB.

The connecting portion GEa is formed on both side surfaces of the contact portion FPa via the insulating film IF2 in the X-axis direction. The connecting portion GEa extends in the Y-axis direction, connecting the gate electrode GE on the region 2A side (first end side) and the gate electrode GE on the region 2A′ side (second end side). The gate electrode GE and the connecting portion GEa include an integrated n-type polycrystalline silicon film. Therefore, the gate potential is also supplied to the connecting portion GEa from the gate wiring GW. Additionally, the connecting portion GEa is covered by the insulating film IF3.

In the interlayer insulating film IL, a hole CH3 is formed. The hole CH3 is formed to overlap with the contact portion FPa in plain view. The source electrode SE is embedded within the hole CH3. The source electrode SE is electrically connected to the field plate electrode FP and supplies a source potential to the field plate electrode FP.

The source electrode SE and the gate wiring GW may include, for example, a barrier metal film and a conductive film formed on the barrier metal film. The barrier metal film includes, for example, a titanium nitride film, and the conductive film includes, for example, an aluminum film.

The source electrode SE and the gate wiring GW may include a plug layer that fills the holes CH1 to CH3 and a wiring layer formed on the interlayer insulating film IL. In this case, the wiring layer includes the barrier metal film and the conductive film. The plug layer includes a barrier metal film such as a titanium nitride film and a conductive film such as a tungsten film.

### Manufacturing Method of Semiconductor Device

FIGS. 12 to 26 are cross-sectional views illustrating the manufacturing method of a semiconductor device according to the second embodiment, showing the A-A cross-section and B-B cross-section of FIG. 10. As shown in FIG. 12, a semiconductor substrate SUB having an upper surface and a lower surface and an n-type drift region NV is prepared. Next, a trench TR is formed in the semiconductor substrate SUB. The trench TR is formed by the method of the first embodiment. The semiconductor device 2, including the A-A cross-section and B-B cross-section, may be the central portion Center of the semiconductor device 2 or the outer peripheral portion Edge of the semiconductor device 2. It is preferable not to divide the first region 100C and the second region 100E within the same semiconductor device 2 (semiconductor chip), but it does not exclude division.

As shown in FIG. 13, for example, by performing a thermal oxidation process, an insulating film IF1 is formed on the semiconductor substrate SUB, including the inside of the trench TR. The insulation film IF1 includes, for example, a silicon oxide film. The insulation film IF1 may be a laminated film of a thin silicon oxide film formed by thermal oxidation and a thick silicon oxide film formed by the CVD method. Next, through the insulation film IF1, a conductive film CF1 is formed on the semiconductor substrate SUB to fill the inside of the trench TR, for example, by the CVD method. The conductive film CF1 includes, for example, an n-type polycrystalline silicon film.

As shown in FIG. 14, by performing a polishing process using the CMP (Chemical Mechanical Polishing) method, the conductive film CF1 formed outside the trench TR is removed. In this way, the field plate electrode FP is formed to fill the inside of the trench TR through the insulating film IF1.

As shown in FIG. 15, a part of the field plate electrode FP is left as the contact portion FPa (B-B cross-section), and the other part of the field plate electrode FP is selectively recessed (A-A cross-section). First, a resist pattern RP1 is formed to selectively cover the region that will become the contact portion FPa. Next, dry etching is performed using the resist pattern RP1 as a mask. As a result, the field plate electrode FP, except for the contact portion FPa, is selectively recessed.

As shown in FIGS. 16 and 17, the insulation film IF1 is recessed inside the trench TR so that its upper surface position is lower than the upper surface position of the field plate electrode FP. First, as shown in FIG. 16, wet etching is performed using a solution containing hydrofluoric acid, using the resist pattern RP1 as a mask. As a result, the insulation of film IF1 on the semiconductor substrate SUB is removed except around the contact portion FPa, and the insulation of film IF1 inside the trench TR is recessed. Next, the resist pattern RP1 is removed by ashing.

Next, as shown in FIG. 17, wet etching is performed on the entire semiconductor substrate SUB using a solution containing hydrofluoric acid. As a result, the insulation of film IF1 on the semiconductor substrate SUB is removed around the contact portion FPa. The insulating film IF1 formed on the side surface of the field plate electrode FP is recessed, and the upper part of the field plate electrode FP is exposed.

At this point, the position of the upper surface of the insulating film IF1 in contact with the field plate electrode FP, excluding the contact portion FPa, is lower than the position of the upper surface of the insulating film IF1 in contact with the contact portion FPa. Additionally, by removing the insulating film IF1 on the semiconductor substrate SUB, the position of the upper surface of the contact portion FPa is higher than the position of the upper surface of the semiconductor substrate SUB.

By creating a step between the upper surface of the contact portion FPa and the upper surface of the insulating film IF1, the connecting portion GEa, described later, is more easily processed into a sidewall shape, making it easier to leave the connecting portion GEa on both side surfaces of the contact portion FPa.

As shown in FIG. 18, by performing thermal oxidation, a gate insulating film GI, including a silicon oxide film, is formed on the semiconductor substrate SUB, including the interior of the trench TR. Through this thermal oxidation process, an insulating film IF2 is formed on the upper and side surfaces of the field plate electrode FP exposed from the insulating film IF1.

Next, as shown in the process of FIG. 15, a conductive film CF2 is formed on the semiconductor substrate SUB, including the interior of the trench TR, by, for example, a CVD method, so as to fill the interior of the trench TR on the field plate electrode FP that has receded (A-A cross-section). Here, a conductive film CF2 is also formed inside the trench TR where the contact portion FPa is formed (B-B cross-section). The conductive film CF2 includes, for example, an n-type polycrystalline silicon film.

As shown in FIG. 19, by performing anisotropic dry etching on the conductive film CF2, the conductive film CF2 formed outside the trench TR is removed, and a gate electrode GE is formed inside the trench TR (A-A cross-section). Through this anisotropic dry etching process, the conductive film CF2 inside the trench TR where the contact portion FPa is formed is processed into a sidewall shape as a connecting portion GEa, and the connecting portion GEa is formed on both side surfaces of the contact portion FPa as part of the gate electrode GE via the insulating film IF2 (B-B cross-section).

In order to completely remove the conductive film CF2 outside the trench TR, the anisotropic dry etching process is performed with over-etching, so the position of the upper surface of the gate electrode GE becomes slightly lower than the position of the upper surface of the semiconductor substrate SUB (A-A cross-section).

As shown in FIG. 20, an insulating film IF3 is formed on the upper surface of the semiconductor substrate SUB, for example, by a CVD method, so as to cover the trench TR. The insulation film IF3 may include, for example, a silicon oxide film or a silicon nitride film.

As shown in FIG. 21, anisotropic dry etching is performed on the insulating film IF3. As a result, the insulating film IF3 remains on part of the upper surface of the gate electrode GE, in contact with the gate insulating film GI (A-A cross-section), and the connecting portion GEa is covered by the insulating film IF3 (B-B cross-section).

As shown in FIG. 22, first, on the upper surface side of the semiconductor substrate SUB, a p-type body region PB is formed in the semiconductor substrate SUB by introducing, for example, boron (B) through ion implantation. The body region PB is formed to be shallower than the trench TR. Next, after covering the periphery of the contact portion FPa with a resist pattern, an n-type source region NS is formed in the body region PB by introducing, for example, arsenic (As) through ion implantation. Then, the resist pattern is removed by ashing. Subsequently, heat treatment is applied to the semiconductor substrate SUB to diffuse the impurities contained in the source region NS and the body region PB.

Before the ion implantation of the source region NS and the body region PB, a thin silicon oxide film may be formed on the semiconductor substrate SUB as a thorough film. This through film may be removed after ion implantation or may remain as part of the interlayer insulating film IL.

As shown in FIG. 23, an interlayer insulating film IL is formed on the upper surface of the semiconductor substrate SUB, for example, by a CVD method, so as to cover the trench TR. The interlayer insulating film IL may include, for example, a silicon oxide film. The interlayer insulating film IL may also be a laminated film of a thin silicon oxide film formed by a CVD method and a PSG film formed by a coating method.

As shown in FIGS. 24 and 25, holes CH1, CH2, and CH3 are formed in the interlayer insulating film IL. Here, although hole CH2 is not shown, hole CH2 is formed in the same process as forming hole CH3.

First, as shown in FIG. 24, a resist pattern RP2 having a pattern for opening the semiconductor substrate SUB where the source region NS is formed is formed on the interlayer insulating film IL. Next, by performing dry etching using the resist pattern RP2 as a mask, a hole CH1 is formed in the interlayer insulating film IL, the source region NS, and the body region PB. The bottom of hole CH1 is located within the body region PB.

Next, by introducing, for example, boron (B) into the body region PB at the bottom of hole CH1 through ion implantation, a p-type high-concentration region PR is formed. Then, the resist pattern RP2 is removed by ashing.

Next, as shown in FIG. 25, a resist pattern RP3 having a pattern for opening the contact portion FPa, the first end of the gate electrode GE on the region 2A side, and the second end of the gate electrode GE on the region 2A′ side is formed on the interlayer insulating film IL. Next, by performing dry etching using the resist pattern RP3 as a mask, holes CH3 and CH2 are formed in the interlayer insulating film IL. Hole CH3 is formed to overlap with the contact portion FPa in a plan view. Hole CH2 is formed to overlap with the first end and the second end in a plan view. Then, the resist pattern RP3 is removed by ashing. Note that the process of forming hole CH1 and the process of forming holes CH2 and CH3 may be performed in either order.

Next, as shown in FIG. 26, a source electrode SE and a gate wiring GW are formed on the interlayer insulating film IL. First, a laminated film includes a barrier metal film containing, for example, a titanium nitride film and a conductive film containing, for example, an aluminum film is formed on the interlayer insulating film IL by a sputtering method or a CVD method. Next, by patterning the laminated film, the source electrode SE and the gate wiring GW are formed.

The gate wiring GW is embedded in hole CH2 and electrically connected to the gate electrode GE. The source electrode SE is embedded in holes CH1 and CH3 and electrically connected to the source region NS, the body region PB, the high-concentration region PR, and the field plate electrode FP.

Next, although not shown here, a protective film containing, for example, a polyimide film is formed on the source electrode SE and the gate wiring GW by, for example, a coating method. By opening a part of the protective film, the regions that become the source pad SP and the gate pad GP of the source electrode SE and the gate wiring GW are exposed.

Thereafter, through the following processes, semiconductor device 2 shown in FIG. 11 is manufactured. First, if necessary, the lower surface of the semiconductor substrate SUB is polished. Next, by introducing, for example, arsenic (As) or the like through ion implantation into the lower surface of the semiconductor substrate SUB, an n-type drain region ND is formed. Then, a drain electrode DE is formed under the lower surface of the semiconductor substrate SUB by a sputtering method.

According to this embodiment, the depth of the trench TR of the MOSFET with a split-gate structure can be made uniform. Therefore, the yield of the semiconductor device 2 can be improved, and the reliability of the semiconductor device 2 can be enhanced.

Although the invention made by the present inventor has been specifically described based on the comparative example, the first embodiment, and the second embodiment, the present invention is not limited to the comparative example, the first embodiment, and the second embodiment, and it goes without saying that various modifications can be made without departing from the gist thereof. For example, combinations of the configurations of the comparative example, the first embodiment, and the second embodiment as appropriate are also within the scope of the technical idea of the embodiment. Additionally, the following configurations are also within the scope of the technical idea of the embodiment.

### Additional Statement 1

A method of manufacturing a semiconductor device comprising:

(a) preparing a semiconductor substrate of a first conductivity type having an upper surface and a lower surface;
(b) after step (a), forming a trench in the semiconductor substrate to reach a predetermined depth from the upper surface and extend in a first direction in a plan view;
(c) after step (b), forming a first insulating film inside the trench;
(d) after step (c), forming a field plate electrode to fill the inside of the trench via the first insulating film;
(e) after step (d), selectively recessing other parts of the field plate electrode so that a part of the field plate electrode remains as a contact portion;
(f) after step (e), recessing the first insulating film inside the trench so that the position of its upper surface becomes lower than the position of the upper surface of the field plate electrode;
(g) after step (f), forming a gate insulating film on the semiconductor substrate inside the trench and forming a second insulating film on the upper and side surfaces of the field plate electrode exposed from the first insulating film;
(h) after step (g), forming a gate electrode on the recessed field plate electrode to fill the inside of the trench;
(i) after step (h), forming an interlayer insulating film on the upper surface of the semiconductor substrate to cover the trench;
(j) after step (i), forming a first hole, a second hole, and a third hole in the interlayer insulating film; and
(k) after step (j), forming a source electrode and a gate wiring surrounding the source electrode in a plan view on the interlayer insulating film,
wherein the gate electrode includes a first end in the first direction and a second end located opposite the first end in the first direction;
wherein the contact portion is formed inside the trench positioned between the gate electrode on the first end side and the gate electrode on the second end side;
wherein the first hole is formed to overlap with the first end in a plan view. The second hole is formed to overlap with the second end in a plan view;
wherein the third hole is formed to overlap with the contact portion in a plan view;
wherein the gate wiring is embedded in the first hole and the second hole and is electrically connected to the gate electrode;
wherein the source electrode is embedded in the third hole and is electrically connected to the field plate electrode,
wherein in step (h), a connecting portion that connects the gate electrode on the first end side and the gate electrode on the second end side is formed inside the trench where the contact portion is formed, as part of the gate electrode;
wherein step (b) includes:
forming a first mask covering the first region and the second region on the first surface;
patterning the first mask in the first region and the second region;
forming a second mask covering the patterned first mask;
patterning the second mask to expose the first region of the first mask and cover the second region of the first mask;
etching the semiconductor substrate in the first region using the patterned first mask and the patterned second mask as a mask;
removing the second mask; and
etching the semiconductor substrate in the first region and the second region using the patterned first mask as a mask.

### Additional Statement 2

In the method of manufacturing a semiconductor device according to Additional statement 1, the contact portion and the connecting portion each extend in the first direction, and the connecting portion is formed on the side surface of the contact portion via the second insulating film in the second direction intersecting the first direction in a plan view.

### Additional Statement 3

In the method of manufacturing a semiconductor device according to Additional statement 2, step (h) includes:
(h1) forming a conductive film on the semiconductor substrate including the inside of the trench; and
(h2) performing anisotropic etching on the conductive film to form the gate electrode on the field plate electrode recessed in step (e) and forming the connecting portion on the side surface of the contact portion via the second insulating film.

### Additional Statement 4

In the method of manufacturing a semiconductor device according to Additional statement 3, the conductive film is made of a polycrystalline silicon film.

### Additional Statement 5

In the method of manufacturing a semiconductor device according to Additional statement 1, the method further comprises:
(l) after step (h) and before step (i), forming a body region of a second conductivity type opposite to the first conductivity type in the semiconductor substrate on the upper surface side shallower than the trench;
(m) after step (l) and before step (i), forming a source region of the first conductivity type in the body region;
(n) after step (i) and before step (k), forming a fourth hole in the interlayer insulating film, the source region, and the body region; and
(o) after step (k), forming a drain electrode under the lower surface of the semiconductor substrate,
wherein the source electrode is embedded in the fourth hole and is electrically connected to the source region and the body region.

### Additional Statement 6

In the method of manufacturing a semiconductor device according to Additional statement 1, the gate wiring is in direct contact with at least one of the first end or the second end.

### Additional Statement 7

In the method of manufacturing a semiconductor device according to Additional statement 1, the gate electrode is electrically insulated from the field plate electrode by the second insulating film and is electrically insulated from the semiconductor substrate by the gate insulating film.

What is claimed is:

1. A method of manufacturing a semiconductor device, the method comprising:
preparing a semiconductor substrate having an upper surface and a lower surface;
forming a first mask having a plurality of openings on the upper surface divided into a first region and a second region;
forming a second mask which exposes a portion of the first mask arranged in the first region and covers a portion of the first mask arranged in the second region;
etching the semiconductor substrate in the first region using the first mask and the second mask as a mask;
removing the second mask; and
etching the semiconductor substrate in the first region and the second region using the first mask as a mask.

2. The method according to claim 1,
wherein the first region includes a central portion of the upper surface, and the second region includes a peripheral portion of the upper surface.

3. The method according to claim 1, further comprising:
obtaining an in-plane distribution of an etching depth at an upper surface of a test semiconductor substrate when etching the test semiconductor substrate containing the same material as the semiconductor substrate using the first mask as a mask, and
dividing the first region and the second region based on the in-plane distribution.

4. The method according to claim 3,
wherein obtaining the in-plane distribution comprises:
preparing the test semiconductor substrate;
forming the first mask on the upper surface;
etching the test semiconductor substrate using the first mask as a mask; and
obtaining an etching depth at a plurality of positions at the upper surface of the etched test semiconductor substrate.

5. The method according to claim 3, further comprising:
obtaining a difference between the etching depth of the divided first region and the etching depth of the divided second region,
wherein etching the semiconductor substrate in the first region comprises etching the semiconductor substrate based on the obtained difference.

6. The method according to claim 5,
wherein etching the semiconductor substrate in the first region and etching the semiconductor substrate in the first region and the second region are performed using plasma.

7. The method according to claim 1,
wherein forming the first mask comprises patterning the plurality of openings for forming a trench in the semiconductor substrate.

8. The method according to claim 1,
wherein the first mask includes a hard mask, and
wherein the second mask includes a photoresist.

9. The method according to claim 1,
wherein forming the first mask comprises:
forming a first mask material on the upper surface;
forming a third mask material on the first mask material;
exposing the third mask material of a portion corresponding to the plurality of openings or a portion other than the plurality of openings;
forming a third mask by removing a portion corresponding to the plurality of openings of the third mask material while leaving a portion other than the plurality of openings;
forming the first mask by etching the first mask material using the third mask as a mask; and
removing the third mask.

10. The method according to claim 1,
wherein forming the second mask comprises:
forming a second mask material on the first mask;
exposing the second mask material of a portion corresponding to the first region or a portion corresponding to the second region; and
forming a second mask by removing a portion corresponding to the first region of the second mask material while leaving a portion corresponding to the second region.

11. A method of manufacturing a semiconductor device, the method comprising:
(a) preparing a semiconductor substrate of a first conductivity type having an upper surface and a lower surface;
(b) after the (a), forming a trench in the semiconductor substrate to reach a predetermined depth from the upper surface of the semiconductor substrate and to extend in a first direction in plan view;
(c) after the (b), forming a first insulating film inside the trench;
(d) after the (c), forming a field plate electrode to fill an inside of the trench via the first insulating film;
(e) after the (d), selectively recessing other parts of the field plate electrode so that a part of the field plate electrode remains as a contact portion;
(f) after the (e), recessing the first insulating film inside the trench so that a position of an upper surface of the first insulating film becomes lower than a position of an upper surface of the field plate electrode;
(g) after the (f), forming a gate insulating film on the semiconductor substrate inside the trench and forming a second insulating film on an upper surface and a side surface of the field plate electrode exposed from the first insulating film;
(h) after the (g), forming a gate electrode to fill an inside of the trench on the field plate electrode recessed in the (e);
(i) after (h), forming an interlayer insulating film on the upper surface of the semiconductor substrate to cover the trench;
(j) after (i), forming a first hole, a second hole, and a third hole in the interlayer insulating film; and
(k) after (j), forming a source electrode and a gate wiring surrounding the source electrode in plan view on the interlayer insulating film,
wherein the gate electrode includes a first end in a first direction and a second end located opposite the first end in the first direction;
wherein the contact portion is formed inside the trench positioned between the gate electrode on the first end side and the gate electrode on the second end side;
wherein the first hole is formed to overlap the first end in plan view;
wherein the second hole is formed to overlap the second end in plan view;
wherein the third hole is formed to overlap the contact portion in plan view;
wherein the gate wiring is embedded in the first hole and the second hole and is electrically connected to the gate electrode;
wherein the source electrode is embedded in the third hole and is electrically connected to the field plate electrode;
wherein in the (h), a connecting portion that connects the gate electrode on the first end side and the gate electrode on the second end side is formed inside the trench where the contact portion is formed, as a part of the gate electrode;
wherein the (b) comprises:
forming a first mask having a plurality of openings on the upper surface of the semiconductor substrate divided into a first region and a second region;
forming a second mask that exposes a portion of the first mask arranged in the first region and covers a portion of the first mask arranged in the second region;
etching the semiconductor substrate in the first region using the first mask and the second mask as a mask;
removing the second mask;
etching the semiconductor substrate in the first region and the second region using the first mask as a mask; and
removing the first mask.

12. The method according to claim 11,
wherein the first region includes a central portion of the upper surface, and the second region includes a peripheral portion of the upper surface.

13. The method according to claim 11, further including:
obtaining an in-plane distribution of an etching depth at an upper surface of a test semiconductor substrate when etching the test semiconductor substrate containing the same material as the semiconductor substrate using the first mask as a mask; and
dividing the first region and the second region based on the in-plane distribution.

14. The method according to claim 13,
wherein obtaining the in-plane distribution comprises:
preparing the test semiconductor substrate;
forming the first mask on the upper surface;
etching the test semiconductor substrate using the first mask as a mask; and
obtaining an etching depth at a plurality of positions at the upper surface of the etched test semiconductor substrate.

15. The method according to claim 13, further comprising:
obtaining a difference between the etching depth of the divided first region and the etching depth of the divided second region,
wherein etching the semiconductor substrate in the first region is based on the obtained difference.

16. The method according to claim 15,
wherein etching the semiconductor substrate in the first region and etching the semiconductor substrate in the first region and the second region are performed using plasma.

17. The method according to claim 11,
wherein forming the first mask comprises patterning the plurality of openings for forming a trench in the semiconductor substrate.

18. The method according to claim 11,
wherein the first mask includes a hard mask, and
wherein the second mask includes a photoresist.

19. The method according to claim 11,
wherein forming the first mask comprises:
forming a first mask material on the upper surface;
forming a third mask material on the first mask material;
exposing the third mask material of a portion corresponding to the plurality of openings or a portion other than the plurality of openings;
forming a third mask by removing a portion corresponding to the plurality of openings of the third mask material while leaving a portion other than the plurality of openings;
forming the first mask by etching the first mask material using the third mask as a mask, and;
removing the third mask.

20. The method according to claim 11,
wherein forming the second mask comprises:
forming a second mask material on the first mask;
exposing the second mask material of a portion corresponding to the first region or a portion corresponding to the second region; and
forming a second mask by removing a portion corresponding to the first region of the second mask material while leaving a portion corresponding to the second region.
